(19) United States
(12) Patent Application Publication
(10) Pub. No.: US 2009/0308451 A1
(43) Pub. Date: Dec. 17, 2009

(54) ARRANGEMENT FOR THE INDIRECT INTENSITY-SELECTIVE ILLUMINATION OF SOLAR CELLS

(75) Inventors: Eduard OESTERLE, Immenstaad (DE); Eberhard SCHUTTE, Friedrichshafen (DE)

Correspondence Address: GREENBLUM & BERNSTEIN, P.L.C., 1950 ROLAND CLARKE PLACE, RESTON, VA, 20191, US

(73) Assignee: ASTRIUM GMBH, Muenchen (DE)

(21) Appl. No.: 12/484,791

(22) Filed: Jun. 15, 2009

(30) Foreign Application Priority Data
Jun. 16, 2008 (DE) 102008028285.5-22

(51) Int. Cl. H01L 31/00

(52) U.S. Cl. 136/256

(57) ABSTRACT

An arrangement and method for illumination of solar cells. The arrangement includes at least one mirror with at least one predetermined surface geometry and at least one solar cell. The at least one predetermined surface geometry is structured and arranged to distribute primary radiation striking the at least one mirror in one of a targeted manner and homogenously on the at least one solar cell.

### CROSS-REFERENCE TO RELATED APPLICATIONS

The present application claims priority under 35 U.S.C. § 119 of German Patent Application No. 10 2006 028 285.5 filed Jun. 16, 2008, the disclosure of which is expressly incorporated by reference herein in its entirety.

### BACKGROUND OF THE INVENTION

1. Field of the Invention

The invention relates to an arrangement for the indirect intensity-selective illumination of solar cells.

2. Discussion of Background Information

The direct exposure of solar cells to the light source is known in the prior art. This has the disadvantage that overexposure and overheating (and consequently a decline in efficiency and damage) of solar cells by primary radiation of high intensity easily occur. Conventional solar generators usually cannot be used, e.g., for satellite orbits close to the sun because of overheating.

### SUMMARY OF THE INVENTION

The invention provides an arrangement that makes it possible to illuminate solar cells in a targeted manner (optimally), so that, e.g., the risk of overheating due to primary radiation of high intensity is reduced. Feasibility of solar generators for use under these conditions is to be made possible.

The controlled exposure of the solar cells advantageously results in a reduction of the solar cell temperature and thus an increase in efficiency.

Furthermore, the controlled exposure of the solar cells results in the possibility of a static or variable adjustment of the radiation intensity of solar cells to the intensity of the primary source (e.g., the sun). This results in particular in the feasibility of solar generators for use in satellite orbits close to the sun and far from the sun.

The invention is directed to an arrangement for the illumination of solar cells that includes at least one mirror with at least one predetermined surface geometry and at least one solar cell. Primary radiation strikes the at least one mirror and is distributed on the solar cells in a targeted manner through the surface geometries of the at least one mirror.

The arrangement according to the invention can furthermore include at least one type of protective reflector. The solar cells are positioned essentially parallel to the primary radiation, so that the superfluous energy passes through the reflectors or the solar cells or is reflected back to the source or into the space by protective reflectors (SR).

There is furthermore the case that at least two types of protective reflectors are arranged such that the solar cells are protected from direct radiation in the case of alignment errors.

One advantageous embodiment of the invention results when the radiation intensity of the at least one solar cell is controlled by the use of one or more mirrors with a flat or shaped surface geometry. According to the invention, the shaped surface geometries are thereby to be designed depending on the case (optionally shaped in a flat or cylindrical or parabolic or other manner, optionally described via a higher order polynomial) such that the radiation intensity is distributed homogenously over the cells. Furthermore, there is the case that the surface geometries are selected to be shaped in a cylindrical as well as parabolic or other manner.

Furthermore, the arrangement according to the invention can be designed such that the beams reflected by the mirrors completely or in part are guided into the (free) cold space and/or into absorbing media.

According to the invention, moveable mirrors with variable geometry can also be used.

Another advantageous embodiment of the invention results when a ratio between the primary-side and secondary-side radiation intensity is controlled statically or dynamically by the rotation or repositioning of the mirrors.

Furthermore, the arrangement described above can be used in all of its embodiments for solar orbits, wherein an indirect or direct illumination takes place with a moveable solar generator.

Embodiments of the invention are directed to an arrangement for illumination of solar cells. The arrangement includes at least one mirror with at least one predetermined surface geometry and at least one solar cell. The at least one predetermined surface geometry is structured and arranged to distribute primary radiation striking the at least one mirror in one of a targeted manner and homogenously on the at least one solar cell.

According to embodiment of the present invention, the arrangement can further include at least one type of protective reflector. The at least one solar cell may be positioned essentially parallel to the primary radiation.

In accordance with other embodiments, the arrangement may include at least two types of protective reflectors that are arranged to protect the at least one solar cell from direct radiation. The direct radiation can result from alignment errors.

Further, the predetermined surface geometry may include at least one of a flat and shaped surface geometry arranged to control radiation intensity of the at least one solar cell. The shaped surface geometry can include at least one of a flat, cylindrical and parabolic surface.

According to embodiments of the instant invention, the at least one mirror may be arranged to guide reflected beams one of completely or in part into at least one of a cold space and absorbing media.

Moreover, the at least one mirror can be structured and arranged for movement and structured with a variable at least one predetermined surface geometry.

According to other embodiments, a ratio between a primary-side and a secondary-side radiation intensity may be controlled statically or dynamically by one of a rotation or repositioning of the at least one mirror.

Embodiments of the invention are directed to an apparatus for illuminating solar cells in solar orbits. The apparatus includes at least one mirror with at least one predetermined surface geometry and at least one moveable solar generator includes at least one solar cell. A positioning of the moveable solar generator controls one of indirect and direct illumination on the at least one solar cell. For indirect illumination on the at least one solar cell, the moveable solar generator can be positioned so the at least one predetermined surface geometry distributes primary radiation striking the at least one mirror at least one of in a targeted manner and homogeneously on the at least one solar cell. Further, for indirect illumination on the at least one solar cell, the moveable solar generator can be positioned essentially in line with the primary radiation. For direct illumination on the at least one solar cell, the moveable solar generator is positioned so the at least one solar cell faces the primary radiation.

Further embodiments of the invention are directed to a method for illuminating solar cells. The method includes positioning at least one mirror with at least one predetermined surface geometry in primary radiation, and distributing the primary radiation striking the at least one predetermined surface geometry in one of a targeted manner and homogenously on at least one solar cell.

In accordance with still further embodiments of the present invention, the method can further include protecting the at least one solar cell from direct contact with the primary radiation. The protecting can include positioning a first and second reflector to form a slot through which the primary radiation strikes the at least one mirror. Further, the first reflector, located between the at least one solar cell and a source of the primary radiation, can have an end forming a part of the slot, and the second reflector, located near an other part of the slot, can be arranged to protect the at least one solar cell from side radiation.

Other exemplary embodiments and advantages of the present invention may be ascertained by reviewing the present disclosure and the accompanying drawing.

### BRIEF DESCRIPTION OF THE DRAWINGS

The present invention is further described in the detailed description which follows, in reference to the noted plurality of drawings by way of non-limiting examples of exemplary embodiments of the present invention, in which like reference numerals represent similar parts throughout the several views of the drawings, and wherein:

FIG. 1 illustrates an arrangement of solar cells according to embodiments of the invention;

FIG. 2 illustrates an arrangement of solar cells according to other embodiments of the invention; and

FIG. 3 illustrates an arrangement of solar cells according to further embodiments of the invention.

### DETAILED DESCRIPTION OF THE PRESENT INVENTION

The particulars shown herein are by way of example and for purposes of illustrative discussion of the embodiments of the present invention only and are presented in the cause of providing what is believed to be the most useful and readily understood description of the principles and conceptual aspects of the present invention. In this regard, no attempt is made to show structural details of the present invention in more detail than is necessary for the fundamental understanding of the present invention, the description taken with the drawings making apparent to those skilled in the art how the several forms of the present invention may be embodied in practice.

FIG. 1 shows a diagrammatic embodiment of the invention. The arrangement of FIG. 1 shows a main mirror and solar cells. There can be one or more solar cells (e.g., so-called strings or entire solar panels). Likewise the invention is described in FIG. 1 for only one main mirror only to simplify matters. However, it is not limited to this case, but can be used likewise for the case of several mirrors.

The primary radiation (e.g., solar radiation) strikes the mirrors and is distributed on the solar cells in a targeted manner by the surface geometry of the mirrors.

According to the invention, the radiation intensity of the solar cells is controlled by the use of one or more mirrors with flat and/or shaped (cylindrical, parabolic or other depending on the case) surface geometry. The surface geometries of the mirrors can thereby be different.

Furthermore, the power flux density of the radiation on the solar cells is reduced by dissipation of the energy or optical methods. To this end the arrangement, which comprises solar cells and mirrors, is to be designed such that the beams reflected fully or in part by the mirrors are conducted into the (free) cold space and/or into absorbing media, such as, e.g., the mirrors themselves.

The case is particularly advantageous where the solar cells are positioned essentially parallel to the solar radiation so that the superfluous energy passes through the reflectors or the solar cells or according to a further embodiment is reflected back to the source or into the free space by protective reflectors (SR).

Particularly advantageous embodiments result furthermore from the use of moveable reflectors with variable geometry. In this case the ratio between the primary-side and secondary-side radiation intensity can be controlled statically or dynamically by the rotation or the repositioning of the reflectors.

An increase of the efficiency of the solar cells can be achieved through the adjustment of the working temperature of the solar cells. In particular this makes solar generators feasible for use at all under extreme environmental conditions such as, e.g., in satellite orbits close to the sun or far from the sun.

According to the invention conventional materials can be used for the reflecting surfaces of the reflectors, such as, e.g., aluminum alloys with targeted adjustment of the reflectance (alpha/epsilon) or partially transparent materials.

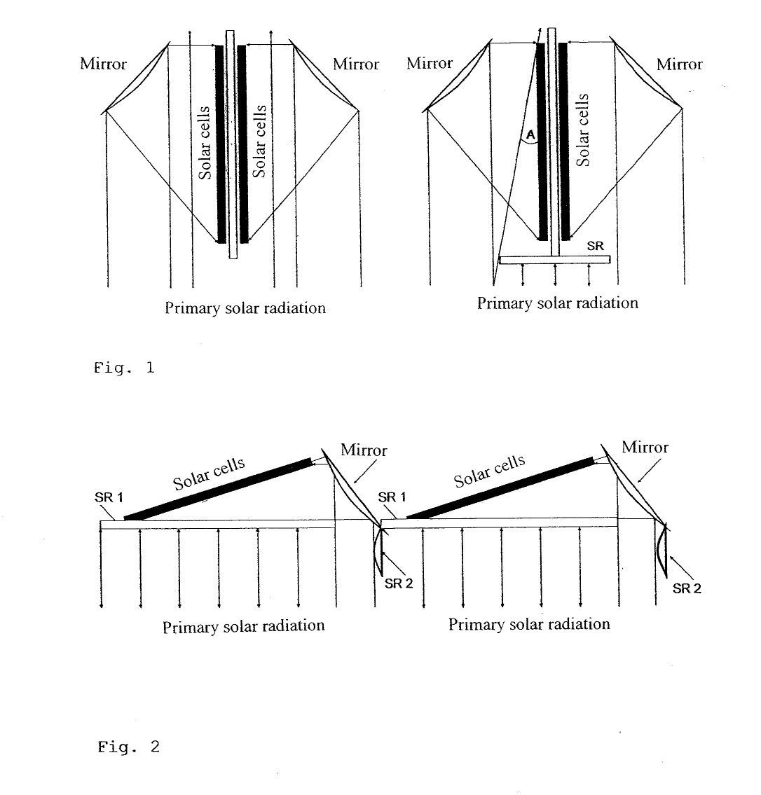

Another embodiment of the invention is shown in FIG. 2. In addition to the solar cells and the main mirror of the first embodiment, the arrangement shown comprises at least two types of protective reflectors (SR1, SR2). To simplify matters, only two types of protective reflectors, a main mirror and solar cells are shown in FIG. 2. Protective reflectors protect the cells from direct radiation in the event of alignment errors, wherein error tolerance is determined by the angle A.

However, the invention is not restricted thereto, but can be used for any number of these elements.

Arrangement according to FIG. 2 shows a one-sided placement, which shows the solar cells with imprecise or faulty alignment to the source of the primary radiation (e.g., solar radiation) (the solar cells are shown in FIG. 2 approx. 45° to the direction of the primary radiation). The parts of the source radiation (primary radiation) to be used for power conversion reach the reflector through a slot and are distributed on the cells such that the power flux density of the radiation is reduced in a targeted manner and is homogenous on the surface of the cells. The rest of the primary radiation is reflected back to the source or into the free or absorbing space by the protective reflectors.

The second two-sided protective reflector protects the solar cells from the side radiation. The energy arriving from the left side is distributed by the curvature of the protective reflector in a dissipating manner on the cells directly or via the reflecting surface.

This has the advantage that the solar generator (comprising several solar cells) is less susceptible to alignment errors or loss of the control and converts or delivers energy even with imprecise alignment to the radiation source. The residual energy is radiated by the cells via the rear of the solar generator.

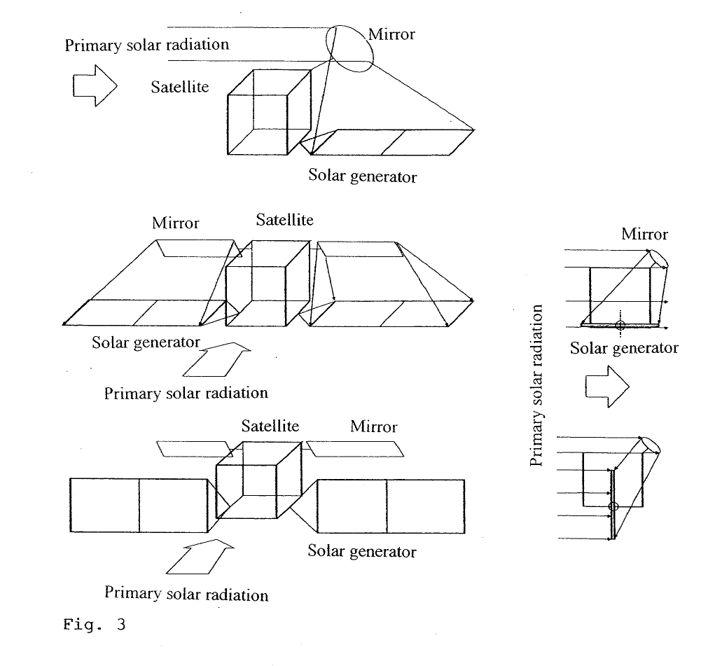

FIG. 3 shows an embodiment of the invention in which entire panels according to this invention can be illuminated. The solar generator (moveable in 1 axis) can thereby be positioned parallel near to the sun and indirectly illuminated by the mirrors and, with a greater distance from the sun, directly illuminated by orthogonal alignment to the solar radiation. In this manner, solar generators in accordance with the embodiments of the invention are particularly well suited for satellites. Design or geometry of the mirrors must be adapted to the respective uses.

It is noted that the foregoing examples have been provided merely for the purpose of explanation and are in no way to be construed as limiting of the present invention. While the present invention has been described with reference to an exemplary embodiment, it is understood that the words which have been used herein are words of description and illustration, rather than words of limitation. Changes may be made, within the purview of the appended claims, as presently stated and as amended, without departing from the scope and spirit of the present invention in its aspects. Although the present invention has been described herein with reference to particular means, materials and embodiments, the present invention is not intended to be limited to the particulars disclosed herein; rather, the present invention extends to all functionally equivalent structures, methods and uses, such as are within the scope of the appended claims.

What is claimed:

1. An arrangement for illumination of solar cells, comprising:
at least one mirror with at least one predetermined surface geometry; and
at least one solar cell,
wherein the at least one predetermined surface geometry is structured and arranged to distribute primary radiation striking the at least one mirror in one of a targeted manner and homogenously on the at least one solar cell.

2. The arrangement in accordance with claim 1, further comprising at least one type of protective reflector, wherein the at least one solar cell is positioned essentially parallel to the primary radiation.

3. The arrangement in accordance with claim 1, further comprising at least two types of protective reflectors that are arranged to protect the at least one solar cell from direct radiation.

4. The arrangement in accordance with claim 3, wherein the direct radiation results from alignment errors.

5. The arrangement in accordance with claim 1, wherein the predetermined surface geometry comprises at least one of a flat and shaped surface geometry arranged to control radiation intensity of the at least one solar cell.

6. The arrangement in accordance with claim 5, wherein the shaped surface geometry comprises at least one of a flat, cylindrical and parabolic surface.

7. The arrangement in accordance with claim 1, wherein the at least one mirror is arranged to guide reflected beams one of completely or in part into at least one of a cold space and absorbing media.

8. The arrangement in accordance with claim 1, wherein the at least one mirror is structured and arranged for movement and structured with a variable at least one predetermined surface geometry.

9. The arrangement in accordance with claim 1, wherein a ratio between a primary-side and a secondary-side radiation intensity is controlled statically or dynamically by one of a rotation or repositioning of the at least one mirror.

10. An apparatus for illuminating solar cells in solar orbits, comprising:
at least one mirror with at least one predetermined surface geometry; and
at least one moveable solar generator comprising at least one solar cell,
wherein a positioning of the moveable solar generator controls one of indirect and direct illumination on the at least one solar cell.

11. The apparatus in accordance with claim 10, wherein for indirect illumination on the at least one solar cell, the moveable solar generator is positioned so the at least one predetermined surface geometry distributes primary radiation striking the at least one mirror at least one of in a targeted manner and homogeneously on the at least one solar cell.

12. The apparatus in accordance with claim 10, wherein for indirect illumination on the at least one solar cell, the moveable solar generator is positioned essentially in line with the primary radiation.

13. The apparatus in accordance with claim 10, wherein for direct illumination on the at least one solar cell, the moveable solar generator is positioned so the at least one solar cell faces the primary radiation.

14. A method for illuminating solar cells, comprising:
positioning at least one mirror with at least one predetermined surface geometry in primary radiation; and
distributing the primary radiation striking the at least one predetermined surface geometry in one of a targeted manner and homogenously on at least one solar cell.

15. The method in accordance with claim 14, further comprising protecting the at least one solar cell from direct contact with the primary radiation.

16. The method in accordance with claim 15, wherein the protecting comprises positioning a first and second reflector to form a slot through which the primary radiation strikes the at least one mirror.

17. The method in accordance with claim 16, wherein the first reflector, located between the at least one solar cell and a source of the primary radiation, has an end forming a part of the slot, and the second reflector, located near an other part of the slot, is arranged to protect the at least one solar cell from side radiation.
